(19) United States
(12) Patent Application Publication
(10) Pub. No.: US 2025/0059099 A1
(43) Pub. Date: Feb. 20, 2025

(54) Method of Cladding Ceramic Optical Fibers

(71) Applicant: Government of the United States as represented by the Secretary of the Air Force, Wright-Patterson AFB, OH (US)

(72) Inventors: Hyunjun Kim, Centerville, OH (US); Randall Hay, Beavercreek, OH (US); Kent Averett, Fairborn, OH (US); Randall Corns, Centerville, OH (US); Benjamin Gray, Centerville, OH (US); Brian Sirn, Fairborn, OH (US)

(21) Appl. No.: 18/802,679

(22) Filed: Aug. 13, 2024

Related U.S. Application Data
(60) Provisional application No. 63/519,569, filed on Aug. 15, 2023.
(60) Provisional application No. 63/519,393, filed on Aug. 14, 2023.

(51) Int. Cl. C04B 35/622; C04B 35/44; C04B 35/626; C04B 35/634; C04B 35/645

(52) U.S. Cl. CPC C04B 35/62236; C04B 35/44; C04B 35/62655; C04B 35/62675; C04B 35/634; C04B 35/6455; C04B 2235/3222; C04B 2235/6021; C04B 2235/606; C04B 2235/6562; C04B 2235/6565; C04B 2235/6567

(57) ABSTRACT

A method of forming a crystalline core/crystalline clad (C4) optical fiber. The method comprises coextruding a cladding mixture of a plasticizer and a binder with a yttrium aluminum garnet (YAG) core. The coextrusion dynamically clads a polycrystalline cladding onto the YAG core to yield a green C4 optical fiber. The C4 optical fiber is then densified, preferably in two steps sintering and hot isostatic pressing. The resulting optical C4 fiber has greater power capacity than a glass fiber labor host.

### CROSS REFERENCE TO RELATED APPLICATIONS

This application claims priority to and the benefit of provisional application Ser. No. 63/519,393 filed Aug. 14, 2023 and provisional application Ser. No. 63/519,569 filed Aug. 15, 2023, the disclosures of which are incorporated herein by reference.

### STATEMENT OF GOVERNMENT INTEREST

The invention described and claimed herein may be manufactured, licensed and used by and for the Government of the United States of America for all government purposes without the payment of any royalty.

### FIELD OF THE INVENTION

The present invention is related to cladded ceramic optical fibers and more particularly to such fibers having polycrystalline cladding.

### BACKGROUND OF THE INVENTION

The principle of data transfer through optic fiber cables is based on the phenomenon of total internal reflection. When a light ray moves from a medium of higher refractive index into a medium of lower refractive index, the light ray bends away from the normal. The normal is a perpendicular to the surface boundary of the two media at the point at which the light ray meets the surface boundary.

During optical signal transmission, light is shone along a thin glass fiber and as it hits the glass-air boundary at more than the critical angle it reflects along inside the fiber. A beam of light travels through one or more fibers and as long as the angle of incidence with the walls of a fiber is great enough, the light will be reflected along the fiber with multiple off-axis.

Since the 1950's it has been known that cladding of a fiber urges the optical signals being transmitted to remain confined to the core and not be dissipated when the signal travels a long distance. Cladding is a layer of material with a lower refractive index that covers the core of a fiber optic cable. The core of the fiber optic cable has a higher refractive index than the cladding circumscribing the core. The refractive index of a medium is a ratio between the speed of light in a vacuum to the speed of light in that medium.

Adding cladding increases the critical angle between the core and only those rays that are close to the axis of the fiber pass through. Additionally, with cladding the light rays travel roughly the same distance in the fiber, so that information input at one end of the fiber arrives at the other end with less time dispersion and increased fidelity. And there are fewer reflections along the fiber compared to the distance travelled without cladding, thereby reducing energy loss and the time of transmission.

By confining the light within the core, the cladding helps to minimize signal loss due to leakage of light, thereby maintaining the strength and fidelity of the transmitted signals over long distances. Cladding also provides the benefits of reduced dissipation of the optical signal due to irregularities in the core and overall recued fiber diameter. The cladding also helps to prevent crosstalk between adjacent fibers by confining the light within the core of each fiber. Outside of the cladding may be a coating for protection against environmental and mechanical hazards.

Ceramic optical fibers clad with dense polycrystalline ceramics may be used for communication, fiber lasers and optical fibers. Previous attempts to clad ceramic optical fibers resulted in the cladding having an improper thickness or were otherwise unsuitable for cladding relatively long fibers, i.e. greater than 2.5 cm. in length. Furthermore, crystalline cladding made according to the prior art by liquid phase epitaxy is frequently contaminated by the elements in flux, negatively impacting signal transmission. Furthermore liquid phase epitaxy is difficult to scale due to requiring a crucible which limited volume. Furthermore, cladding according to the crystalline deposition of the prior art is prone to faceting and irregularities. Furthermore, splicing clad optical fibers together is difficult and damage to the prior art cladding may cause the fiber to fail.

These problems are substantially overcome by the present invention. There is a need for cladding ceramic optical fibers with dense polycrystalline ceramics that readily controls the thickness of the cladding, and that may be scaled up for cladding on long fibers, i.e., fibers longer than 2.5 cm.

### SUMMARY OF THE INVENTION

In one embodiment the invention comprises a method of forming a crystalline core/crystalline clad (C4) optical fiber. The method comprises the steps of: providing a coextrusion mixture comprising cladding material powder, plasticizer and a binder, and optionally a solvent in a pressurized vessel; the pressurized vessel having a coextrusion mixture inlet for receiving the coextrusion mixture, a core inlet for receiving an elongate yttrium aluminum garnet (YAG) core having an outer surface and an extrusion nozzle for extruding a green C4 fiber therethrough; drawing the YAG core into the core inlet, through the pressurized vessel and outwardly through the extrusion nozzle to dynamically clad the coextrusion mixture within the vessel onto the outer surface of the core to yield a green C4 fiber; and then densifying the green C4 fiber to yield an optically transparent C4 fiber.

The densifying step may occur in two stages: sintering followed by hot isostatic pressing. The resulting fiber has a YAG core and polycrystalline cladding.

### BRIEF DESCRIPTION OF THE DRAWINGS

FIG. 1 is schematic. All other figures are to scale.

FIG. 1 is a schematic side elevational view of a co-extrusion apparatus suitable for use with the present invention.

FIG. 2A is a photograph of an assembled co-extrusion apparatus suitable for use with the present invention with the nozzle at the three-oclock position.

FIG. 2B is a photograph of the co-extrusion apparatus of FIG. 2A disassembled.

FIG. 3 is a photograph of the co-extrusion apparatus of FIGS. 2A and 2B connected to a pump.

FIG. 4 is a photograph of a green-cladded fiber under tension for drying and an un-tensioned fiber for control.

FIG. 5 is a photograph of a co-extruded single crystal YAG core fiber clad with a dried undoped YAG cladding according to the present invention.

FIG. 6 is a photograph of a binder removed clad fiber having been vacuum sintered.

FIG. 7A is a fragmentary photomicrograph of a polished cross-section of the cladded and sintered fiber of FIG. 6.

FIG. 7B is a photomicrograph of a polished cross-section of a cladded and hot isostatic pressed fiber.

FIG. 8A is a photomicrograph of a polished cross-section of a cladded and hot isostatic pressed fiber.

FIG. 8B is an enlarged photomicrograph of the fiber of FIG. 8A.

FIG. 8C is a further enlarged photomicrograph of the fiber of FIG. 8A having the core highlighted at 16 discrete points around the circumference.

### DETAILED DESCRIPTION OF THE INVENTION

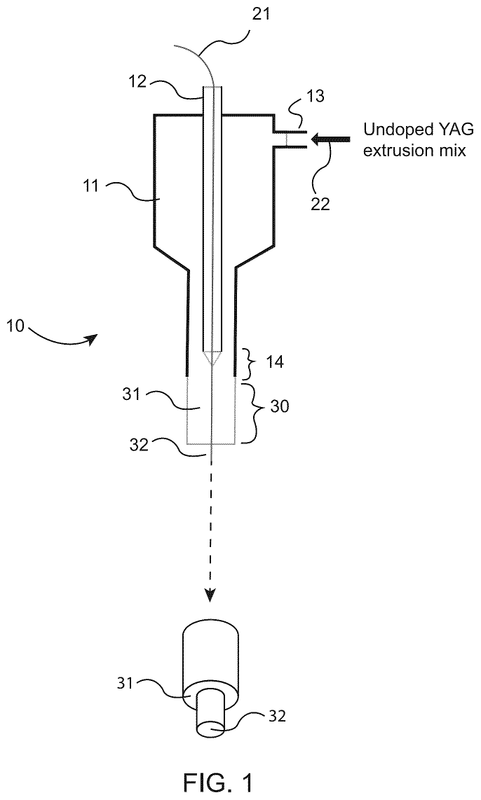

Referring to FIG. 1, an apparatus 10 according to and for carrying out the claimed invention produces an elongate fiber 30 having a core 32 circumscribed by a preferably circumjacent cladding 31. The fiber 30 is a crystalline core 32/green crystalline clad 31 (C4) optical fiber 30. Advantageously, the invention unexpectedly provides a polycrystalline cladding 31. Polycrystalline cladding 31 is preferred over monocrystalline cladding 31 are believed to have generally equal power transmission capabilities in the fiber 30. Polycrystalline cladding 31 also allows for longer fibers 30, such as up to 100 kM in length. The present invention provides the benefit over the prior art

The apparatus 10 comprises a core 32 precursor 21 feed tube 12, an extrusion head 11 circumscribing the tube 12 and an adjoining, preferably contiguous, nozzle 14 in fluid communication with both the tube 12 and head 11. The apparatus is preferably, but not necessarily, round. The nozzle 14 is preferably coaxial with, concentric with and smaller than the head 11. This apparatus 10 and method provide for coextrusion of the core 32 and cladding 31, at extrusion speeds of 1 cm/sec. to 10 cm/sec and preferably about 5 cm/sec.

The tube 12 receives a precursor 21 which becomes the core 32 of a fiber 30 having cladding 31 circumscribing the core 32. The head 11 receives an extrusion mixture 22 through an inlet 13 which is remote from the inner tube 12. The extrusion mixture 22 circumscribes the precursor 21 at a confluence with the nozzle 14, and cures to become the cladding 31. In one exemplary embodiment the inside diameter of the head 11 inlet 13 is 1 mm at the proximal end, the OD (outside diameter) and ID (inside diameter) of the inner tube 12 are 340 and 180 microns, respectively. The inner tube 12 may be 3.8 cm long from the proximal end to the distal end. The ID of the nozzle 14 may range from 0.75 mm to 5 mm and preferably about 1 mm.

More particularly, the process described and claimed herein is useful for the cladding 31 of a ceramic optical core 32 with polycrystalline ceramics. The process for cladding 31 ceramic fibers 30 with polycrystalline materials is carried out by co-extrusion and subsequent densification. In the co-extrusion process, a ceramic core 32 precursor 21 is co-extruded through an extrusion nozzle 14 with a wet powder mixture 22 of cladding 31 material. After extrusion and drying, the cladded fiber 30 is sintered or preferably sintered and hot isostatically pressed and densified to be transparent as an optical fiber 30 with cladding 31. It is believed that the cladding 31 cannot be adequately densified using only hot isostatic pressing (HIP). Using both sintering and HIP provides improved transparency of the cladding 31 and better optical signal transmission.

This apparatus 10 is particularly useful for co-extrusion of a dense core 32 fiber 30 having a green cladding 31. The co-extrusion head 11 may have an inner tube 12 through which the core 32 precursor 21 is drawn, and an outer head 11 which surrounds the inner tube 12 and through which the extrusion/cladding 31 mixture 22 is injected by a pump.

The extruded cladding 31 material is preferably a particulate powder mixed with organics. Suitable organics include a binder and a plasticizer. The binder bonds the particles together after drying, preferably solvent drying. The plasticizer provides flexibility to the dried green body. A polymer material that is solvent soluble may be used for the binder. Hydroxypropyl methylcellulose ether, polyethyleneimine, polyvinyl butyral, and polyvinyl alcohol are suitable polymers. Hydroxypropyl methylcellulose ether is water soluble and has been found to work well. Suitable hydroxypropyl methylcellulose is available from The Dow Chemical Co. of Midland, MI under the name Methocel™ Glycerol is a suitable plasticizer.

The coextrusion has been successfully made and used at room temperature. The coextrusion consists of ceramic powder, e.g., Yttrium Aluminum Garnet (YAG) powder was used with a YAG core 32 fiber 30 in this case, binder, plasticizer, and solvent, e.g., water. YAG is preferred over glass for the core 32 of the fiber 30 due to having a greater thermal conductivity, advantageously improving heat removal. Localized heating generates uneven refractive index distribution, negatively impacting transmission and possibly resulting in failure of a glass fiber 30. For example, defects in the fiber 30 can undesirably convert light to heat, dissipating energy and degrading signal transmission.

The mass ratio of binder to plasticizer is preferably about 3:2. A 100% binder without plasticizer composition is feasible, but a 100% plasticizer composition is infeasible. The volume ratio of ceramic powder and organics, i.e., binder plus plasticizer, ranges from 10:1.5 to 10:5 and preferably is about 10:3. The mixture 22 contains 30-40 weight percent of water. The viscosity of mixture 22 preferably ranges from 7000 cps to 200000 cps and more preferably ranges from 10000 cps to 60000 cps in order to be self-supporting.

Following coextrusion, the green-cladded fiber 30 is then densified by sintering followed by hot isostatic pressing (HIP). By green it is meant that the cladding 31 ceramic is dried but not fired yet.

In operation, this mixture 22 is loaded into a high-pressure pump, preferably a syringe pump, which is connected to the inlet 13 of the co-extrusion head 11. The core 32 precursor 21 is inserted into the proximal end the inner tube 12. Extrusion begins, and the core 32 precursor 21 is cladded with the mixture 22 in the nozzle 14 upon exiting the distal end of the inner tube 12. After co-extrusion and drying, the core 32 of the fiber 30 is cladded to yield an optical fiber 30.

The core 32 fiber 30 moves through the head 11 under the pressure exerted by the pump. The exiting coextrusion mixture 22 draws the core 32 fiber 30 out of the head 11. During the drying step, the green-clad core 32 fiber 30 will have a tendency to curl, which may be undesirable. The curl is due to shrinkage of the cladding 31 material, and the drying shrinkage mismatch between the dense core 32 fiber 30 and the wet cladding 31. It was discovered that the application of tension during the drying process will prevent curling.

Accordingly, the fiber 30 is preferably dried under tension. Tension may be applied by any known manner, such as a weight attached to an end of the core 32 fiber 30. The weight may be 20 g to 50 g for a fiber 30 of 12 cm to 16 cm, in order to ensure proper tension. Drying may be carried out at room temperature overnight. Prophetically draw rolls could be used to tension the fiber 30, so long as the cross section of the fiber 30 is not unduly deformed.

Evaporative removal of the organic (binder) component may be accomplished by heating the fiber 30 from room temperature to a range of 300° C. to 900° C., preferably 550° C. to 700° C., and more preferably 600° C., for from 2 hours to 24 hours, and preferably from 6 hours to 18 hours in oxygen or air, and soaking at 600° C. for 30 minutes. Soaking means holding the fiber 30 at that temperature for a predetermined period. Evaporative removal may take 6 to 18 hours to reach 600° C. from room temperature and to hold at 600° C. for 30 minutes.

The green fiber is first sintered, then hot isostatically pressed. The sintering step is performed under vacuum. Sintering may trap and usually traps pores within the body to be sintered. These pores may be removed by hot isostatic pressing.

Sintering may be accomplished by heating the fiber 30 from 1650° C. to 1800° C. at a heating rate of 5° C./min to 20° C./min. The fiber 30 is then soaked at temperature for 2-10 hrs, then cooled to room temperature at a cooling rate of 2° C./min to 40° C./min. Sintering is done under a vacuum, air or an oxygen atmosphere. After sintering, hot isostatic pressing (HIP) conditions include heating the fiber 30 at a rate of 5° C./min to 15° C./min to a temperature of 1550° C. to 1700° C., preferably 1600° C. for a period of 1 hor to 7 hours, preferably 5 hours, under 10 ksi to 50 ksi argon and preferably 30 ksi argon. The heating time and temperature are inversely proportional. The fiber 30 is then cooled to room temperature at 5° C./min to 40° C./min.

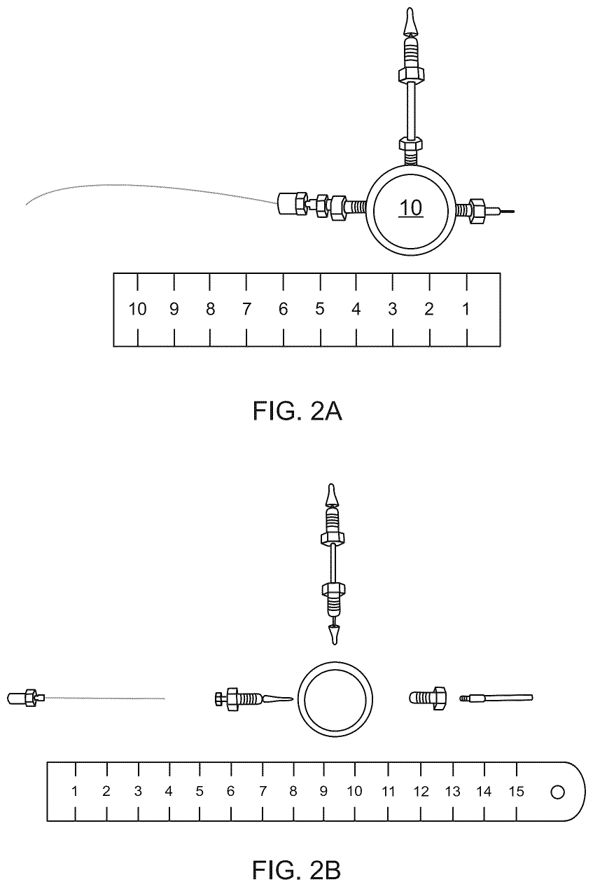

Referring to FIGS. 2A and 2B, an exemplary co-extrusion head 11 suitable for cladding 31 a core 32 fiber 30 and particularly the C4 fiber 30 of the present invention are shown.

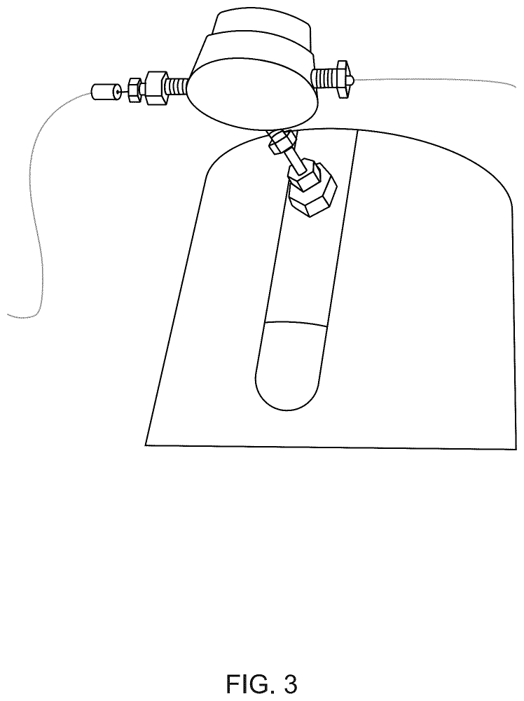

Referring to FIG. 3 the co-extrusion head 11 is mounted to an exemplary syringe pump. The pump may have a flow rate of 0.01 microliters/min to 22 microliters/min for any pressure up to 2068 bar with an operating pressure range of 0.6895 bar to 2068.4 bar. A Model 100DM syringe pump available from Teledyne ISCO of Lincoln, NE has been found suitable.

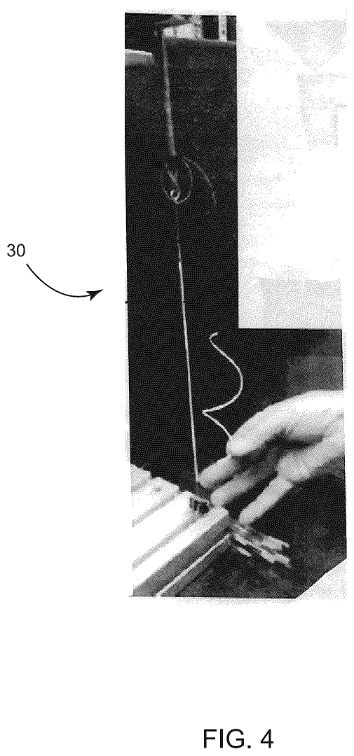

Referring to FIG. 4 a green-cladded C4 fiber 30 is shown drying under tension. A 20-50 g weight may be placed on the end of a C4 fiber 30 having a length of 2.5 cm to 15.3 cm and preferably 3.8 cm to 5.1 cm and preferably with a diameter of 300 microns to 2 mm. A C4 fiber 30 of sufficient weight may have sufficient tension hanging under its own weight.

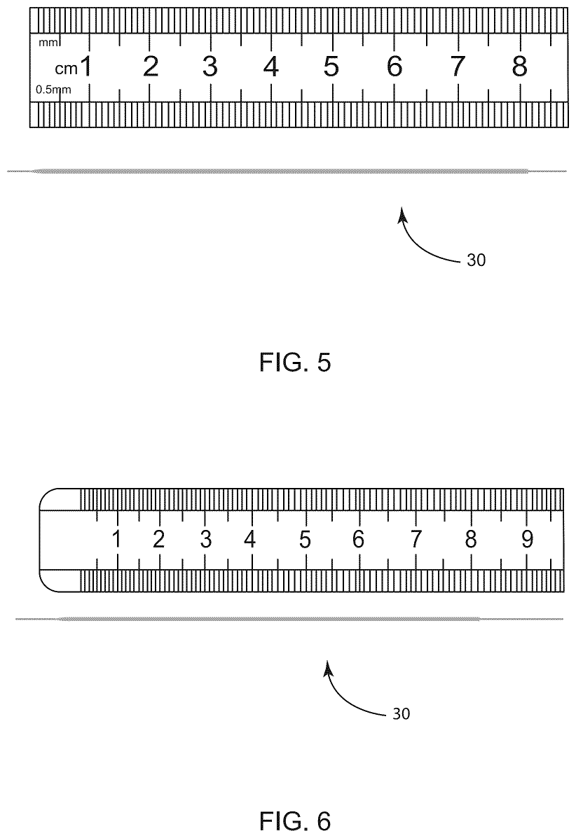

Referring to FIG. 5 a co-extruded single crystal YAG core 32 fiber 30 clad with a dried undoped YAG cladding 31 is shown. Each end of the fiber 30 has the core 32 extending outwardly of the cladding 31.

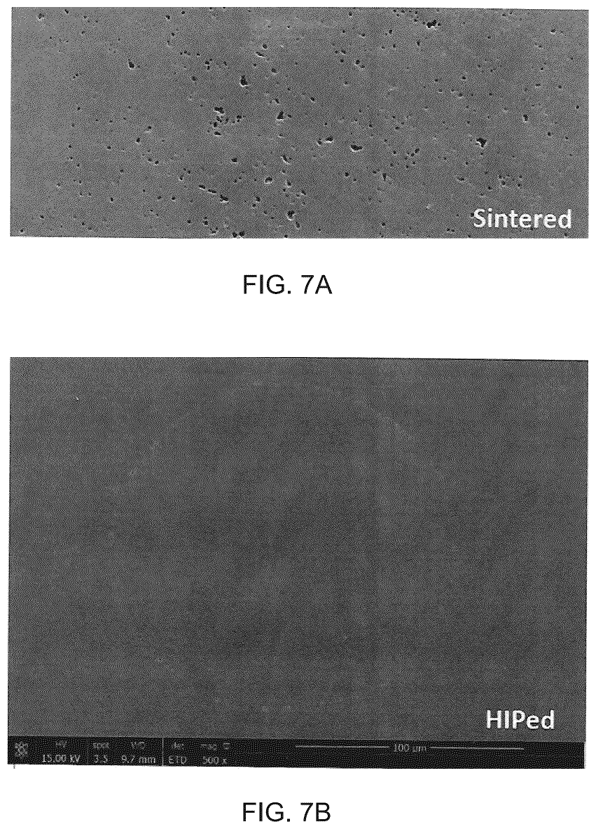

FIG. 6 depicts a C4 fiber 30 that was BRed (binder removed) and vacuum sintered in an alumina tube 12 furnace. This fiber 30 was subjected to heating from room temperature to 600° C. for 18 hrs, soaking at 600° C. for 30 minutes in oxygen, then heating to 1700° C. at a heating rate of 10° C./min, soaking at 1700° C. for 5 hrs and cooling to room temperature at a cooling rate of 40° C./min. The 10° C./min heating, soaking and 40° C./min cooling were carried under mechanical pump vacuum. The resulting co-extruded and dried undoped YAG cladding 31 surrounds a single crystal YAG fiber 30 core 32.

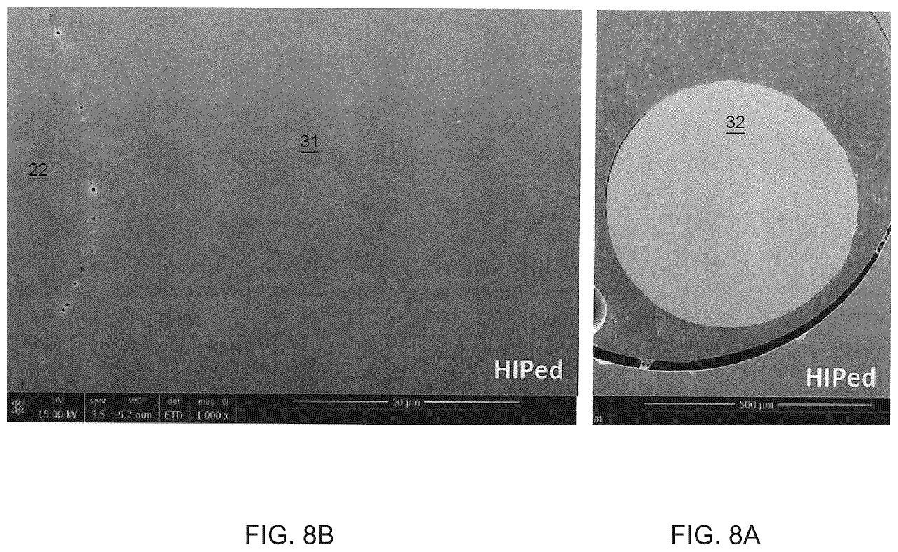

Referring to FIGS. 7A and 7B sintered and HIPed polished cross-sections, respectively, of a cladded C4 fiber 30 and a sintered C4 fiber 30 are shown. FIG. 7A presents a part of a core 32 (a minor arc and a chord of core 32, to the left in the image) and porous cladding 31 after sintering. FIG. 7B presents a cross-section of a core 32 and cladding 31 after HIP. FIG. 7B shows significant porosity reduction in the cladding 31 relative to the sintered fiber 30 due to the HIP.

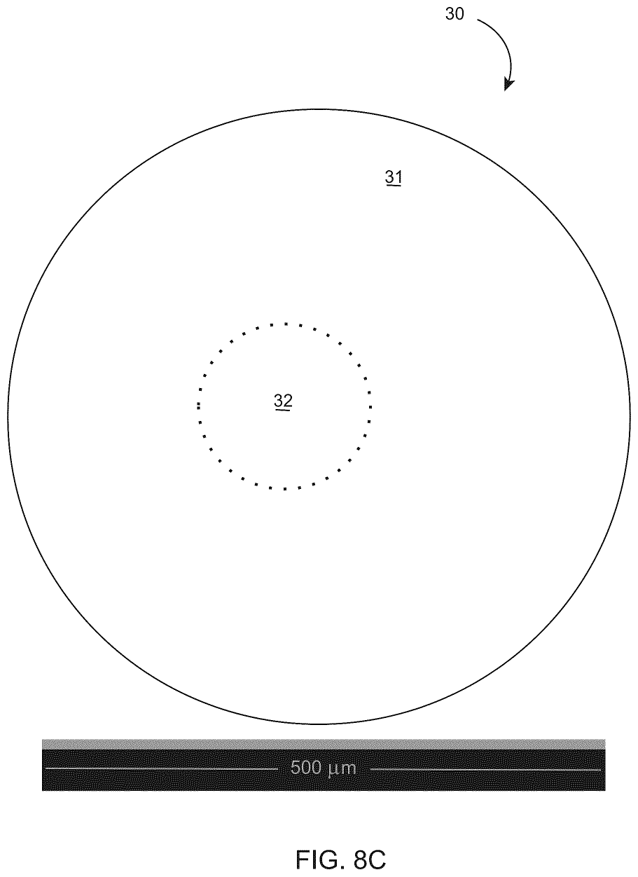

Referring to FIGS. 8A, 8B and 8C HIPed clad fibers 30 are shown. The C4 FIG. 8A is similar to the fiber 30 of FIG. 7A, except that the fiber 30 of FIG. 8A was obtained after the HIP process. FIGS. 8A and 8B show a cross-sectional view of an entire HIPed core 32—clad 31 fiber 30. FIG. 8C shows that upon magnification the core 32 is visible.

In a nonlimiting example of the process according to the present invention, an undoped YAG extrusion mix was utilized as the cladding 31. The YAG extrusion mixture 22 was made from undoped YAG powder, Methocel (binder), glycerol (plasticizer), and water. The YAG powder can range from 40% to 70%, the binder from 2% to 20%, the plasticizer from 0% to 6% and water from 20% to 40% of the extrusion mixture with all percentages being weight percentages. Upon mixing, the viscosity of the extrusion mix 22 at rest ranges from 7000 cps to 200000 cps and is preferably about 150000 cps.

A syringe pump having a discharge pressure of 1000 psi to 1500 psi was used for extrusion. The resulting C4 fiber 30 was dried under tension. Next, the dried clad core 32 C4 fiber 30 was sintered in alumina tube furnace at 1700° C. for 5 hrs. The fiber 30 was densified by sintering, then HIP.

Assuming 50% green density of the cladding 31, isotropic shrinkage of about 20% % should take place for full densification. However, it was found that predominantly radial shrinkage occurred. Shrinkage along the longitudinal axis of the fiber 30 was negligible due to the tension on the green-clad fiber 30. Green density is a density of ceramic body before firing. Density of pressed body of ceramic powder is usually 50% of the theoretical maximum density.

Co-extrusion of undoped YAG cladding 31 and single crystal YAG core 32 was followed by sintering and HIP. Sintering was accomplished at 1675° C. for 5 hrs in a mechanical pump vacuum and HIPed at 1600° C. for 5 hrs under 30 ksi Ar. The sintering temperature can range from 1650° C. to 1675° C.

All values disclosed herein are not strictly limited to the exact numerical values recited. Unless otherwise specified, each such dimension is intended to mean both the recited value and a functionally equivalent range surrounding that value. For example, a dimension disclosed as “40 mm” is intended to mean “about 40 mm.” The term “or” as used herein is to be interpreted as an inclusive or meaning any one or any combination. Therefore, “A, B or C” means “any of the following: A; B; C; A and B; A and C; B and C; A, B and C.” Every document cited herein, including any cross referenced or related patent or application, is hereby incorporated herein by reference in its entirety unless expressly excluded or otherwise limited. The citation of any document or commercially available component is not an admission that such document or component is prior art with respect to any invention disclosed or claimed herein or that alone, or in any combination with any other document or component, teaches, suggests or discloses any such invention. Further, to the extent that any meaning or definition of a term in this document conflicts with any meaning or definition of the same term in a document incorporated by reference, the meaning or definition assigned to that term in this document shall govern according to Phillips v. AWH Corp., 415 F.3d 1303 (Fed. Cir. 2005). All limits shown herein as defining a range may be used with any other limit defining a range of that same parameter. That is the upper limit of one range may be used with the lower limit of another range for the same parameter, and vice versa. As used herein, when two components are joined or connected the components may be interchangeably contiguously joined together or connected with an intervening element therebetween. A component joined to the distal end of another component may be juxtaposed with or joined at the distal end thereof. While particular embodiments of the present invention have been illustrated and described, it would be obvious to those skilled in the art that various other changes and modifications can be made without departing from the spirit and scope of the invention and that various embodiments

What is claimed is:

1. A method of forming a crystalline core/crystalline clad (C4) optical fiber, the method comprising the steps of:
providing a coextrusion mixture comprising a binder, yttrium aluminum garnet (YAG) powder, a binder and optionally a plasticizer, in a pressurized vessel, the pressurized vessel having a coextrusion mixture inlet for receiving the coextrusion mixture, a core inlet for receiving a crystalline core having an outer surface and an extrusion nozzle for extruding a green C4 fiber therethrough;
drawing the YAG core into the core inlet, through the pressurized vessel and outwardly through the extrusion nozzle to dynamically clad the coextrusion mixture within the vessel onto the outer surface of the core to yield a green C4 fiber; and
densifying the green C4 fiber to yield an optically transparent C4 fiber.

2. A method according to claim 1 wherein the YAG core is a single crystal YAG core.

3. A method according to claim 2 wherein the binder of the coextrusion mixture comprises a solvent soluble polymer.

4. A method according to claim 2 wherein the binder of the coextrusion mixture comprises ceramic powder and organic materials and the plasticizer of the coextrusion mixture comprises glycerol.

5. A method according to claim 4 wherein the coextrusion mixture has a viscosity of 7000 cps to 200000 cps.

6. A method according to claim 5 wherein the coextrusion mixture is inserted into the coextrusion inlet, pressure fed through the vessel towards the extrusion nozzle while joined to the core to extrude the core with cladding joined thereto outwardly through the extrusion nozzle to yield the green C4 fiber.

7. A method according to claim 6 wherein the green C4 fiber is extruded at a rate of 1 cm/sec to 5 cm/sec.

8. A method of forming a crystalline core/crystalline clad (C4) optical fiber, the method comprising the steps of:
providing a coextrusion mixture comprising a plasticizer and a binder in a pressurized vessel, the pressurized vessel having a coextrusion mixture inlet for receiving the coextrusion mixture, a core inlet for receiving an elongate yttrium aluminum garnet (YAG) core having an outer surface and an extrusion nozzle for extruding a green C4 fiber therethrough;
drawing the YAG core into the core inlet, through the pressurized vessel and outwardly through the extrusion nozzle to dynamically clad the coextrusion mixture within the vessel onto the outer surface of the core to yield a green C4 fiber;
thermally drying the green C4 fiber; and
densifying the green C4 fiber to yield an optically transparent C4 fiber.

9. A method according to claim 8 wherein the green C4 fiber is densified in two stages.

10. A method according to claim 9 wherein the green C4 fiber is dried by raising the oxygen air temperature from room temperature to a temperature of 550° C. to 700° C. for a period of 6 to 16 hours, then cooling the C4 fiber to 20° C.

11. A method according to claim 10 further comprising the step of applying tension to the green C4 fiber during drying.

12. A method according to claim 11 wherein the two stages of densification comprise sintering followed by hot isostatic pressing.

13. A method of forming a crystalline core/crystalline clad (C4) optical fiber, the method comprising the steps of:
providing a coextrusion mixture comprising a plasticizer and a binder in a pressurized vessel, the pressurized vessel having a coextrusion mixture inlet for receiving the coextrusion mixture, a core inlet for receiving an elongate yttrium aluminum garnet (YAG) core having an outer surface and an extrusion nozzle for extruding a green C4 fiber therethrough;
drawing the YAG core into the core inlet, through the pressurized vessel and outwardly through the extrusion nozzle to dynamically clad the coextrusion mixture within the vessel onto the outer surface of the core to yield a green C4 fiber;
thermally drying the green C4 fiber; and
thermally densifying the green C4 fiber to yield an optically transparent C4 optical fiber.

14. A method according to claim 13 wherein the step of thermally densifying the comprises:
sintering the green C4 fiber by raising the ambient temperature from 20° C. to a temperature of 1550° C. to 1700° C. at a rate of 5° C./min. to 15° C./min.;
holding the green C4 fiber at 1550° C. to 1700° C. for a period of 2 hours to 10 hours; and
cooling the green C4 fiber to 20° C. at a rate of 10° C./min. to 40° C./min.

15. A method according to claim 14 further comprising the step of sintering the C4 fiber under ambient atmosphere following the step of cooling.

16. A method according to claim 15 further comprising the step of hot isostatically pressing the C4 fiber following the step of sintering the C4 fiber.

17. A method according to claim 16 wherein the step of hot isostatically pressing the C4 fiber comprises:
heating the green C4 fiber from room temperature to a range of 1550° C. to 1700° C.;
holding the green C4 fiber at 1550° C. to 1700° C. for a period of 2 hours to 10 hours; and
cooling the green C4 fiber to room temperature.

18. A method according to claim 17 wherein the step of thermally densifying the C4 fiber comprises hot isostatically pressing the C4 fiber in an argon atmosphere.

19. A method according to claim 18 wherein the argon atmosphere is held at a pressure of 10 ksig TO 50 ksig.

20. A method according to claim 18 further comprising the step of sintering the C4 fiber prior to the step of hot isostatically pressing the C4 fiber.
